(19) United States
(12) Patent Application Publication
(10) Pub. No.: US 2012/0147576 A1
(43) Pub. Date: Jun. 14, 2012

(54) MOUNTING APPARATUS FOR POWER SUPPLY

(75) Inventors: PO-WEN CHIU, Tu-Cheng (TW); WEN-HU LU, Shenzhen City (CN); ZHAN-YANG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., ShenZhen City (CN)

(21) Appl. No.: 13/188,200

(22) Filed: Jul. 21, 2011

(30) Foreign Application Priority Data
Dec. 13, 2010 (CN) 201010584953.9

(51) Int. Cl. H05K 5/00

(52) U.S. Cl. 361/759

(57) ABSTRACT

A mounting apparatus includes a chassis, a mounting tray and a securing member. The mounting tray is received in the chassis and includes a side panel. A transferring card is located on the inside of the side panel. The securing member includes a flat base and a securing tray. A positioning portion is located on the flat base, and a sliding hole is defined in the flat base. The securing tray defines a receiving space adapted to receive a power supply connected to the transferring card. The flat base is slidable relative to the side panel between a locked position, where the clasping piece is positioned at a first end of the sliding hole, and the positioning portion is engaged in the positioning hole, and an unlock position, where the clasping piece is positioned at a second end of the sliding hole, and the positioning portion is disengaged from the positioning hole.

### BACKGROUND

1. Technical Field

The present disclosure relates to mounting apparatuses, and particularly to a mounting apparatus for securing a power supply to an electronic device.

2. Description of Related Art

Many computer systems include a main power supply unit and a plurality of supplemental power supplies in a computer case. The supplemental power supplies are used to supply power for electronic components when the main power supply cannot supply sufficient power. The installation of the supplemental power supplies usually involves the use of screws, which is inconvenient.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a partially exploded, isometric view of a mounting apparatus in accordance with an embodiment.

FIG. 2 is similar to FIG. 1, but viewed from a different aspect.

FIG. 3 is an isometric view of a securing member of the mounting apparatus of FIG. 1.

FIG. 4 is an assembled view of FIG. 1.

FIG. 5 is an assembled view of FIG. 2.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

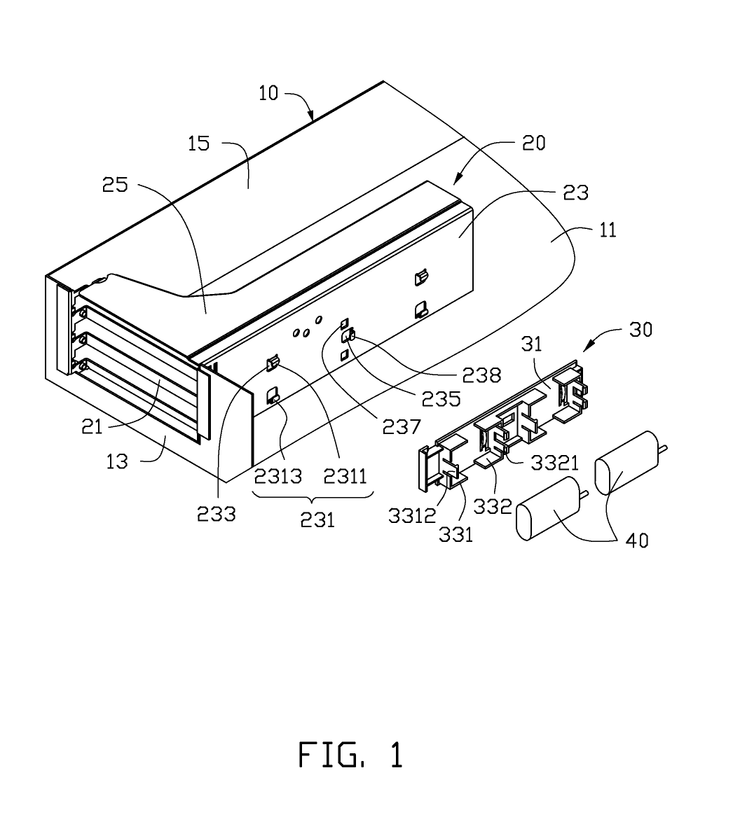

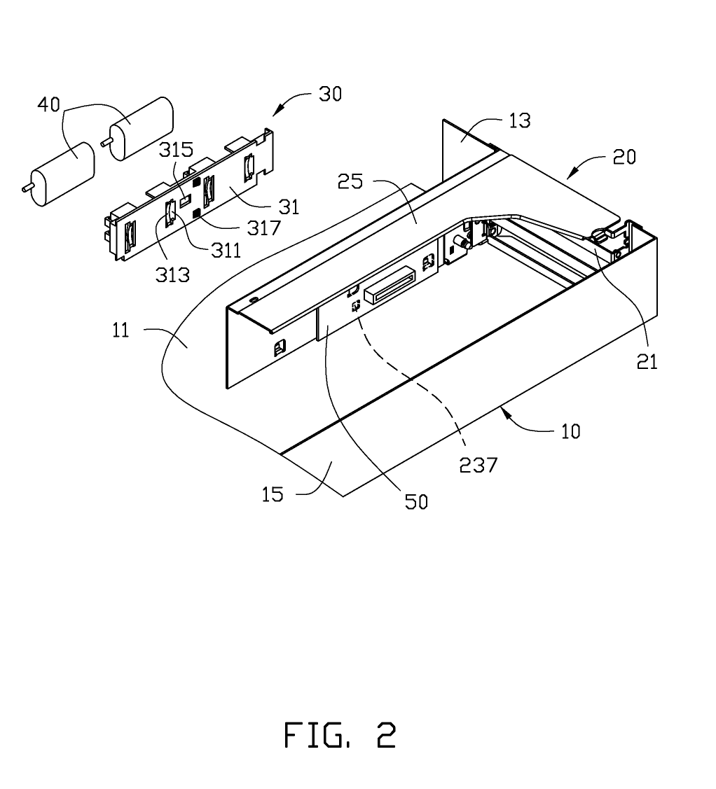

Referring to FIGS. 1 and 2, a mounting apparatus in accordance with an embodiment includes a chassis 10, a mounting tray 20 (only a part is shown) received in the chassis 10, and a securing member 30 secured to the mounting tray 20. The securing member 30 may receive a plurality of power supplies 40 (only two shown). In one embodiment, the power supplies 40 are supplemental power supplies, and are used to supply power for a riser card 50 received in the mounting tray 20.

The chassis 10 includes a bottom plate 11 and a front plate 13, and a side plate 15 connected to the bottom plate 11 and the front plate 13. In one embodiment, the bottom plate 11 is substantially perpendicular to the front plate 13 and the side plate 15.

The mounting tray 20 is secured to the front plate 13 and includes a front panel 21, a side panel 23 connected to the front panel 21, and a top panel 25 connected to the front panel 21 and the side panel 23. In one embodiment, the side panel 23 is substantially perpendicular to the front panel 21 and the bottom plate 11. Two clipping assembles 231 are located on the outside of the side panel 23. Each clipping assembly 231 includes two clipping members (a first clipping member 2311 and a second clipping member 2313) pointing towards each other. In one embodiment, each clipping member is connected to an edge of a first opening 233 defined in the side panel 23.

A second opening 235 is defined in the side panel 23 and located between the two clipping assemblies 231. A clasping piece 238 extends from an edge of the second opening 235 and points toward the front panel 21. Two positioning holes 237 are defined in the side panel 23 and arranged at opposite sides (up and down) of the second opening 235.

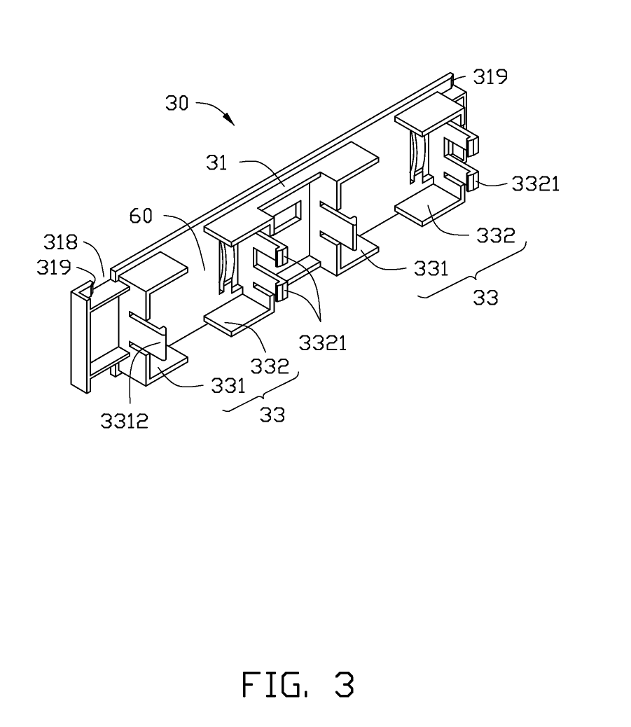

Referring to FIGS. 2-3, the securing member 30 includes a flat base 31 and a plurality of securing trays 33 (only two shown) located on a front side of the flat base 31. Four longitudinal holes 311 are defined in the flat base 31, and an elastic piece 313 is connected to opposite edges of each hole 311. In one embodiment, each elastic piece 313 is arched out to the side having the plurality of securing trays 33. A sliding slot 315 is defined in the flat base 31 and two positioning portions 317 are located on the backside of the flat base 31. The two positioning portions 317 are adjacent to the sliding slot 315 and arranged along a straight line. In one embodiment, the positioning portions 317 may be ribs, or other formed in other configurations which can engage with sides of a hole. An operating hole 318 is defined downwardly in the top edge of the flat base 31. In one embodiment, the operating slot 318 maybe a cutout, which user can use to operate the securing member 30 easily. Two guiding surfaces 319 are located on the flat base 31, and one of the guiding surfaces 319 is towards the operating slot 318. Each guiding surface 319 is slanted for the securing member to slide between the first clipping member 2311 (see FIG. 1) and the second clipping member 2313 easily.

Each securing tray 33 includes a first securing frame 331 and a second securing frame 332 pointing towards the first securing frame 331. The first securing frame 331 and the second securing frame 332 together defines a receiving space 60 for receiving a power supply 40. A first securing portion, such as a hook or clasp (first securing portion 3312), is located on the first securing frame 331 and points toward the second securing frame 332. Two second securing portions, may be hooks or clasps (second securing portion 3321) are located on the second securing frame 332 and point toward the first hook 3312. In one embodiment, each first securing frame 331 and each second securing frame 332 is adjacent to each elastic piece 313.

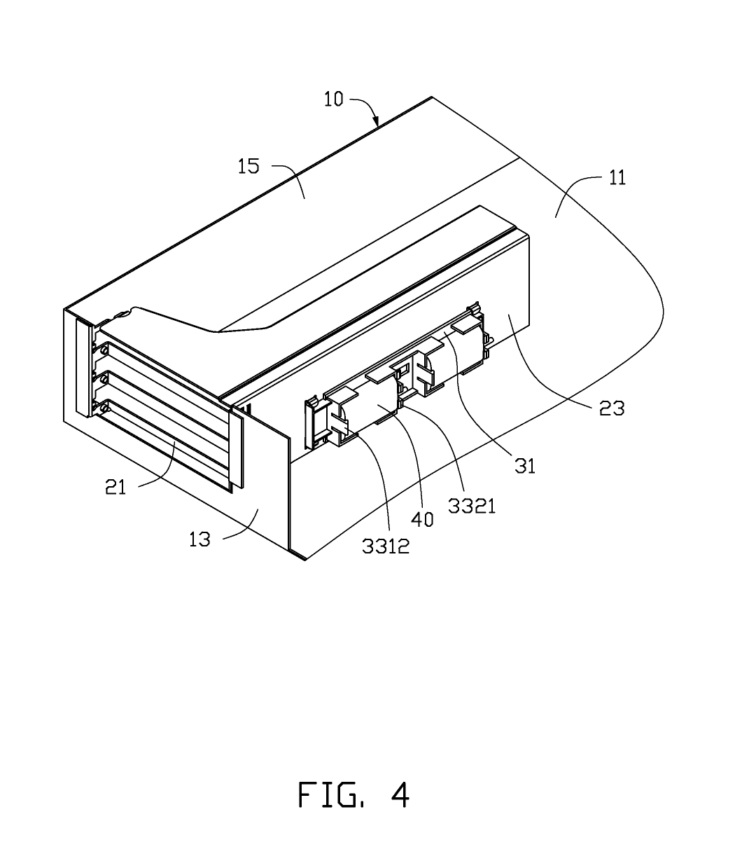

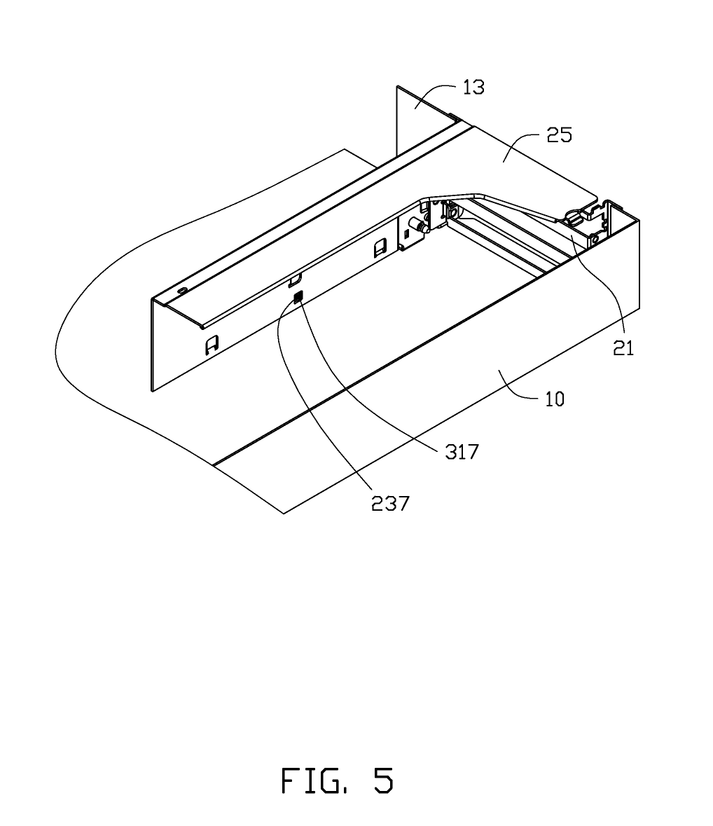

Referring to FIGS. 4-5, in assembly, the flat base 31 abuts the side panel 23 and is positioned between the first clipping member 2311 and the second clipping member 2313. The clasping piece 238 passes through the sliding slot 315 and is positioned in a first end of the sliding slot 315. The securing member 30 is moved along a direction parallel to the side panel 23 and perpendicular to the front panel 21, until the clasping piece 238 is positioned in a second end of the sliding slot 315. Thus, the two positioning portions 317 can be engaged in the two positioning holes 237.

Each power supply 40 abuts the first securing portion 3312 and the second securing portions 3321. The power supply 40 is pressed towards the receiving space 60, to deform the first securing portion 3312 and the second securing portions 3321, until the power supply 40 is received in the receiving space 60. The first securing portion 3312 and the second securing portions 3321 are released to clip the power supply 40. Therefore, the power supply 40 is secured to the securing member 30. The elastic pieces 313 are deformed by the power supply 40 being pressed.

In disassembly, the first securing portion 3312 and the second securing portions 3321 are deformed to disengage from the power supply 40. The elastic pieces 313 are released to drive the power supply 40 to move away from the flat base 31. Therefore, the power supply 40 can be taken out from the receiving space 60.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A mounting apparatus comprising:
a chassis;
a mounting tray received in the chassis and comprising a side panel; a transferring card located on an inside of the side panel; a positioning hole defined in the side panel, and a clasping piece extending outside of the side panel; and
a securing member comprising a flat base and a securing tray located on the flat base, a positioning portion located on the flat base, and a sliding hole defined in the flat base; the securing tray defining a receiving space adapted to receive a power supply connected to the transferring card;
wherein the flat base is slidable relative to the side panel between a locked position, where the clasping piece is positioned in a first end of the sliding hole, and the positioning portion is engaged in the positioning hole, and an unlock position, where the clasping piece is positioned in a second end of the sliding hole, and the positioning portion is disengaged from the positioning hole.

2. The mounting apparatus of claim 1, wherein a first securing portion and a second securing portion are located on the securing tray, and the first securing portion and the second securing portion points toward each other and adapted to clip the power supply.

3. The mounting apparatus of claim 1, wherein the securing tray comprises a first securing frame and a second securing frame pointed towards the first securing frame, and the receiving space is defined by the first securing frame and the second securing frame.

4. The mounting apparatus of claim 3, wherein the first securing frame is substantially perpendicular to the flat base.

5. The mounting apparatus of claim 1, wherein an elastic piece is located on the flat base and towards the receiving space, and the elastic piece is deformable to disengage the power supply from the receiving space.

6. The mounting apparatus of claim 5, wherein the elastic piece is located in a first side of the flat base, and the positioning portion is located on a second opposite side of the flat base.

7. The mounting apparatus of claim 1, wherein a first clipping member and a second clipping member are located on the outside of the side panel, the second clipping member pointed toward the first clipping member, and the first and second clipping member are engaged with the flat base.

8. The mounting apparatus of claim 7, wherein a guiding surface is located on the flat base, and the guiding surface is adapted for the securing member positioned between the first and second clipping member.

9. The mounting apparatus of claim 1, wherein an operating slot is defined in the flat base, and the operating slot is adapted for the securing member to be detached from side panel.

10. A mounting apparatus comprising:
a chassis comprising a front plate;
a mounting tray received in the chassis and comprising a front panel and a side panel substantially perpendicular to the front panel, the front panel attached to the front plate; a transferring card located on the inside of the side panel, a clipping assembly, extending from the side panel, comprising a first clipping member and a second clipping member pointed toward the first clipping member; and a securing member comprising a flat base, a first securing portion and a second securing portion located on the flat base;
wherein the flat base is positioned between the first clipping member and the second clipping member, and the first securing portion and the second securing portion are adapted to clip a power supply.

11. The mounting apparatus of claim 10, wherein a guiding surface is located on the flat base, and the guiding surface is slanted and adapted for the securing member positioned between the first and second clipping member.

12. The mounting apparatus of claim 10, wherein the securing member further comprises a securing tray located on the flat base, the securing tray comprises a first securing frame and a second securing frame pointed toward the first frame, and the first securing frame and the second securing frame define a receiving space adapted to receive the power supply.

13. The mounting apparatus of claim 12, wherein the first securing frame is substantially perpendicular to the flat base.

14. The mounting apparatus of claim 12, wherein an elastic piece is located on the flat base and towards the receiving space, and the elastic piece is deformable to disengage the power supply from the receiving space.

15. The mounting apparatus of claim 14, wherein the elastic piece is arched out to the side having the securing tray.

16. The mounting apparatus of claim 14, wherein a positioning hole is defined in the side panel, and a positioning portion is located on the flat base and received in the positioning hole.

17. The mounting apparatus of claim 16, wherein the elastic piece is located in a first side of the flat base, and the positioning portion is located on a second opposite side of the flat base.

18. The mounting apparatus of claim 10, wherein a sliding hole is defined in the flat base, and a clasping piece extends from the side panel and slidably received in the sliding hole along a direction substantially perpendicular to the front panel.

19. The mounting apparatus of claim 10, wherein an operating slot is defined in the flat base, and the operating slot is adapted for the securing member detached from side panel.
